(19) United States
(12) Patent Application Publication
(10) Pub. No.: US 2025/0221233 A1
(43) Pub. Date: Jul. 3, 2025

(54) Transparent Display Device and Method of Controlling the Same

(71) Applicant: LG Display Co., Ltd., Seoul (KR)

(72) Inventors: Sung Hak Jo, Paju-si (KR); Binn Kim, Paju-si (KR)

(21) Appl. No.: 18/977,317

(22) Filed: Dec. 11, 2024

(30) Foreign Application Priority Data
Dec. 29, 2023 (KR) 10-2023-0197875

(51) Int. Cl. H10K 59/65; H10K 59/13; H10K 102/00

(52) U.S. Cl. CPC H10K 59/65; H10K 59/13; H10K 2102/3031

(57) ABSTRACT

Provided are a transparent display device and a method of controlling the same. The transparent display device includes a sensor configured to measure color characteristics of light incident on the transparent display device, and a transparent display panel configured to display an image in which an input image in a transparent region (non-image area) is corrected based on measured color characteristics so that color distortion is corrected.

### CROSS-REFERENCE TO RELATED APPLICATION

This application claims the benefit of Republic of Korea Patent Application No. 10-2023-0197875, filed on Dec. 29, 2023, which is hereby incorporated by reference in its entirety.

### BACKGROUND

### Field of Technology

The present disclosure relates to a transparent display device, and more particularly, to a transparent display device and a method of controlling the same capable of correcting a tint of a region (transparent region) where a display image is not displayed according to background illumination and screen image of the transparent display device.

### Discussion of the Related Art

Since display panels are utilized are in diverse fields, various types of display panels have been manufactured.

Current flat panel display panels have been implemented as plasma display panels (PDPs), liquid crystal display (LCD) panels, and organic light emitting diode display (OLED) panels.

Recently, usability of display panels has been further expanded, and transparent display panels have been developed and are attracting attention as an expanded field. Such transparent display panels may be implemented as OLED panels that do not require backlight units.

In this way, a transparent display device implemented using an OLED panel, etc., may display various types of image content on a display panel having certain transmittance, and such a transparent display device may be utilized in various fields such as shop windows, billboards, doors of home appliances, and public displays.

### SUMMARY

Accordingly, the present disclosure is directed to a transparent display device and a method of controlling the same that substantially obviate one or more problems due to limitations and disadvantages of the related art.

A transparent display device according to conventional technology tends to have a yellowish tint due to an organic film and a cathode. In addition, a tint of a transparent display panel changes according to illuminance and color temperature of an external light source. Specifically, while there is no change in a tint of the transparent display panel under yellow-colored lighting, a yellowish tint of the transparent display panel becomes visible under white-colored lighting.

The present disclosure presents a transparent display device using an illuminance sensor that may solve conventional problems and expand utilization efficiency and an application range of the transparent display device, and a method of driving the same.

Specifically, a solution task according to an embodiment of the present disclosure is to provide a transparent display device using an illuminance sensor that calculates background conversion illuminance using transmittance and background illuminance of a transparent display panel, so that a display input image in a non-display region may be corrected and displayed according to the calculated background conversion illuminance, and a method of driving the same.

Solution tasks according to an embodiment of the present disclosure are not limited to tasks mentioned above, and other tasks not mentioned herein will be clearly understood by those skilled in the art from the description below.

Effects of the present disclosure are not limited to those illustrated above, and a variety of other effects are included in this specification.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a block diagram of a transparent display device according to an embodiment of the present disclosure;

FIG. 2 is a configuration block diagram illustrating the transparent display device according to an embodiment of the present disclosure;

FIG. 3 is a diagram illustrating an example of a transparent region and a non-transparent region provided in a display area according to an embodiment of the present disclosure;

FIG. 4 is a circuit diagram of a subpixel of the transparent display device according to an embodiment of the present disclosure;

FIG. 5 is a cross-sectional view illustrating an example of I-I′ of FIG. 3 according to an embodiment of the present disclosure;

FIG. 6 is transmittance by wavelength of the transparent display device according to an embodiment of the present disclosure;

FIGS. 7A and 7B are diagrams illustrating each transparent display image according to color of an external light source according to an embodiment of the present disclosure;

FIGS. 8A and 8B are diagrams for describing an improvement point according to color of the external light source according to an embodiment of the present disclosure;

FIGS. 9A and 9B are diagrams for describing a method of improving the transparent display device according to an embodiment of the present disclosure;

FIG. 10 is a block diagram of an image processor according to an embodiment of the present disclosure;

FIG. 11 is a flowchart illustrating a stepwise image processing method according to an embodiment of the present disclosure; and

FIG. 12 illustrates a location of an illuminance/color coordinate sensor of the transparent display device according to an embodiment of the present disclosure.

### DETAILED DESCRIPTION

The advantages and features of the present disclosure, and the method for achieving the advantages and features will become apparent with reference to embodiments described below in detail in conjunction with the accompanying drawings. However, the present disclosure is not limited to the embodiments disclosed below and may be implemented in a variety of different forms, and the present embodiments allow the present disclosure to be complete and are provided to fully inform those of ordinary skill in the art to which the present disclosure pertains of the scope of the disclosure. Further the present disclosure is merely defined by the scope of the claims.

When elements or layers are referred to as being “on” another element or layer, this includes both cases where the other element is directly on top of the other element or layer, and where there is another layer or element interposed therebetween.

Even though the terms first, second, etc. are used to describe various components, it is to be understood that these components are not limited by these terms. These terms are merely used to distinguish one component from another. Accordingly, it is obvious that a first component referred to below may also be a second component within the technical concept of the present disclosure.

In this specification, an image refers to a visual image, and means all elements that appear on a screen or a display device. The image may include a moving image, a still image, a still cut, etc., the moving image may include a plurality of frames, and each of the frames may include a plurality of layers or regions. The image may be a two-dimensional (2D) image or a three-dimensional (3D) image. In this specification, the image is processed for both the case where the image is a 2D image and the case where the image is a 3D image. Therefore, hereinafter, both the 2D image and the 3D image are referred to as images unless specifically mentioned.

In this specification, an image signal refers to a signal converted into an electric signal and output so that an image may be displayed on a screen or a panel of a display device and refers to a signal that allows transmission and reception of image data.

In this specification, image processing or image correction means processing an input image to suit a purpose by signal processing through a processing unit or a processor, and includes both analog signal processing and digital signal processing. Hereinafter, for convenience of description, image processing means digital image processing of an image. However, image processing is not limited thereto and may be broadly interpreted. In addition, image processing in this specification may include at least four types, namely, point processing, region processing, geometric processing, and frame processing. Point processing is performed in units of pixels based on locations of pixels. Region processing may change pixel values based on original values of pixels and values of neighboring pixels, and geometric processing may change locations or arrangement of pixels. Frame processing may change pixel values based on operations on two or more images.

In this specification, a transparent display device means a display device in which at least a partial region of a screen of the display device recognized by a user is transparent. In this specification, transparency of the transparent display device means a level of the transparent display device that allows the user to recognize at least an object behind the display device. In this specification, the transparent display device means, for example, a display device having a transparent display device transmittance of at least 20%. Depending on the transmittance of the transparent display device, the amount of light transmitted through a rear surface of the transparent display device may be determined. In this specification, “incident light” refers to light incident on the transparent display device and transmitted through the transparent display device.

In this specification, a front surface and the rear surface of the transparent display device are defined based on light emitted from the transparent display device. In this specification, the front surface of the transparent display device means a surface where light is emitted from the transparent display device, and the rear surface of the transparent display device means a surface opposite the surface where light is emitted from the transparent display device.

In this specification, color information refers to color characteristics of incident light or a displayed screen, and may be expressed in various color coordinates such as YUV, CMYK, HSV, RGB, etc. However, in this specification, for the convenience of description, a description is given on the assumption that the color information is RGB color coordinates. In addition, each color coordinate may be converted from RGB to HSV or from HSV to RGB, taking into consideration the purpose of use or the amount of calculation, as needed.

The size and thickness of each component shown in the drawings are shown for convenience of description, and the present disclosure is not necessarily limited to the size and thickness of the illustrated components.

Below, the present disclosure is described in detail with reference to the attached drawings.

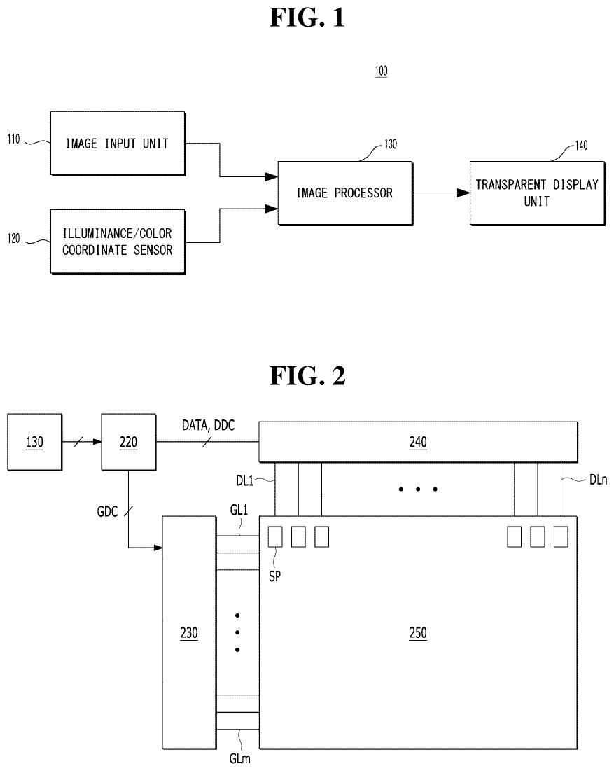

FIG. 1 is a block diagram of a transparent display device including an image processing device according to an embodiment of the present disclosure. The transparent display device 100 according to the embodiment of the present disclosure includes an image input unit 110 (e.g., a circuit), an illuminance/color coordinate sensor 120, an image processor 130, and a transparent display unit 140.

A surrounding environment projected onto the transparent display device 100 has various illuminance environments. For example, indoor illuminance of an office is about 200 to 500 lux, illuminance is about 20,000 to 30,000 lux under shadows of buildings or forests in broad daylight, and illuminance is about 50,000 to 100,000 lux under the midday sun. Due to these usage environments, variables of brightness of light incident on the transparent display device 100 are diverse.

Eyes of the user change depending on the illuminance environment. For example, in a low illuminance environment of 200 lux, the user may clearly visually recognize low-luminance images. However, in an illuminance environment of 30,000 lux, the user cannot clearly visually recognize low-luminance images. Depending on the illuminance environment, the pupils of the user may dilate or contract, so that the user clearly visually recognizes images using a small amount of light, or the pupils of the user may not be able to visually recognize light having high luminance.

Incident light may have color characteristics. The light incident on the transparent display device 100 may have all color information of not only white, but also of natural colors depending on the distribution of intensity by wavelength. The incident light may be lighting, sunlight, etc., and may include different color information depending on the lighting or the location of the sun. For example, an incandescent lamp and a fluorescent lamp may have different color temperatures, and sunlight may include different color information at sunrise, sunset, morning, noon, and afternoon. When light having color information is incident, the light may have a significant impact on visibility of a displayed image. That is, the overall colors of the image displayed together may be distorted by the background of the transparent display device 100, and brightness contrast may be reduced for a specific color.

When light having color information is incident on the transparent display device 100, the transparent display device 100 according to an embodiment of the present disclosure may measure color information of the incident light and correct a color of an image displayed on the transparent display unit 140 based on the measured color information. Therefore, the transparent display device 100 according to the embodiment of the present disclosure may improve visibility of the displayed image and reduce power consumption by controlling light emission of the transparent display unit.

The image input unit 110 receives an image and inputs the image to the image processor 130. The image input unit 110 may receive an image from an external device, a memory of the transparent display device 100, or a wired/wireless reception device. The image input unit 110 may receive input via D-Sub, DVI, HDMI, S-Video, component video, etc. The image input unit 110 inputs the received image to the image processor 130.

The illuminance/color coordinate sensor 120 measures the amount of light incident on the transparent display device 100 including the illuminance/color coordinate sensor 120 and color information of the light and transmits the measured illuminance information and the color information to the image processor 130. Hereinafter, the illuminance/color coordinate sensor 120 may be referred to as an illuminance/color coordinate sensor, a color illuminance sensor, a color photodiode, etc.

The transparent display device 100 may be exposed to various light environments including backlight, direct light, and light conditions of different distributions. The transparent display device 100 may collect information related to various light environments through the illuminance/color coordinate sensor 120 and may be configured to recognize objects on the rear surface and ensure visibility of the image based on information related to the light environments. Hereinafter, the illuminance/color coordinate sensor 120 may be referred to as an optical module, a photodiode, a photo transistor, etc. The illuminance/color coordinate sensor 120 of the transparent display device 100 may include various filters such as an HPF (High Pass Filter), an LPF (Low Pass Filter), a BPF (Band Pass Filter), an ultraviolet film, an infrared film, etc. to measure information only in a specific visible light region. That is, the illuminance/color coordinate sensor 120 of the transparent display device 100 may be configured to filter infrared or ultraviolet light that may be measured as noise.

The illuminance/color coordinate sensor 120 of the transparent display device 100 according to an embodiment of the present disclosure may be configured as one illuminance/color coordinate sensor 120 or may be configured by combining a plurality of illuminance/color coordinate sensors 120. In addition, the illuminance/color coordinate sensor 120 of the transparent display device 100 according to an embodiment of the present disclosure may be disposed in a non-display area of the transparent display device 100 as an independent illuminance/color coordinate sensor 120. In the following, unless specifically mentioned otherwise, for convenience of description, the illuminance/color coordinate sensor 120 is shown as being disposed on the transparent display unit 140. However, the illuminance/color coordinate sensor 120 may be mounted in a non-display area of the transparent display unit.

In the following, the illuminance/color coordinate sensor 120 of the transparent display device 100 according to an embodiment of the present disclosure may be an illuminance/color coordinate sensor 120 configured by combining three illuminance/color coordinate sensors that measure color information of R, G, and B, respectively. However, the illuminance/color coordinate sensor 120 may be configured as one illuminance/color coordinate sensor or may be an image sensor including a plurality of pixels.

A measurement value of light incident on the illuminance/color coordinate sensor 120 of the transparent display device 100 according to an embodiment of the present disclosure may be converted into a digital signal corresponding to R, G, B color coordinates, and the converted signal may be referred to as an R, G, B measurement value of the incident light.

The image processor 130 receives an image from the image input unit 110, receives color information of light incident on the transparent display device 100 from the illuminance/color coordinate sensor, and corrects or processes the image based on the received color information of the light. The image processor 130 may generate an image signal for displaying the image. The image processor 130 may transmit the generated image signal to the transparent display unit 140.

The transparent display unit 140 receives the processed image signal from the image processor 130 and displays an image by outputting the image signal. The transparent display unit 140 performs a function of displaying a result of image processing by the image processor 130. In this specification, the transparent display unit 140 may be a synonym for a transparent indicator, a transparent display, etc. The transparent display device 100 according to an embodiment of the present disclosure may include various transparent display units 140.

The transparent display unit 140 of the transparent display device 100 according to an embodiment of the present disclosure may be a transparent organic light emitting diode display device. The organic light emitting diode display device is a display device that causes an organic light emitting layer to emit light by allowing current to flow through the organic light emitting layer. The transparent organic light emitting diode display device emits light of a specific wavelength by using the organic light emitting layer. The transparent organic light emitting diode display device includes at least a cathode, an organic light emitting layer, and an anode. In addition, the transparent organic light emitting diode display device may include a light emitting region configured to emit display light and a transparent region configured to allow incident light to pass therethrough. Since the transparent region has a structure adjacent to the light emitting region, when light incident on the transparent region is excessively bright, intensity of light of the light emitting region becomes relatively weak, resulting in a problem in that the user actually perceives only the light of the transparent region. Accordingly, a contrast ratio under bright room conditions or gamma curve characteristics under bright room conditions changes variably depending on the brightness of the transparent region.

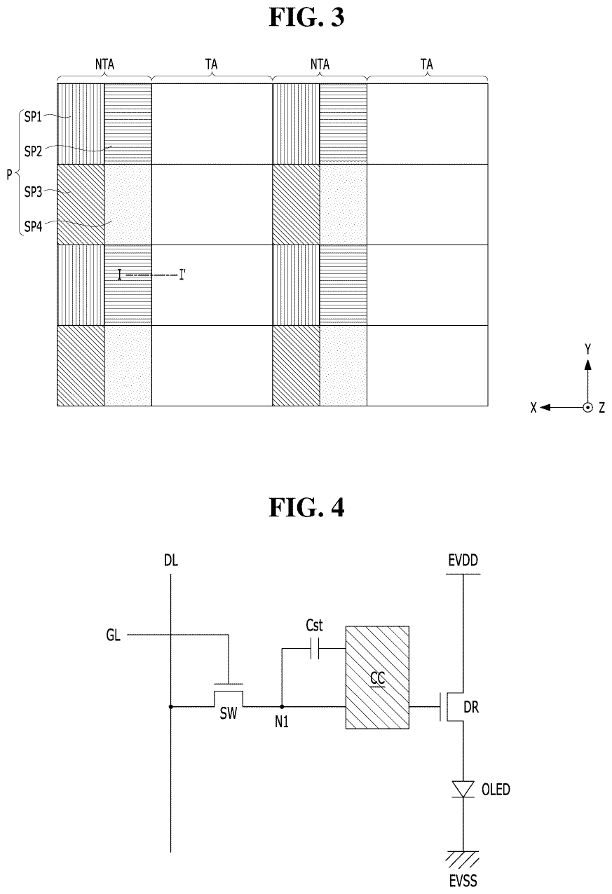

In addition, the transparent display unit 140 may be driven by a passive matrix and an active matrix, and driving of the transparent organic light emitting diode display device is specifically described with reference to FIG. 3.

The transparent organic light emitting diode display device may be configured using a top emission method and a bottom emission method. The organic light emitting diode display device using the top emission method refers to an organic light emitting diode display device in which light emitted from an organic light emitting element is emitted toward an upper side of the organic light emitting diode display device, and refers to an organic light emitting diode display device in which light emitted from the organic light emitting element is emitted toward an upper surface of a substrate on which a thin film transistor for driving the organic light emitting diode display device is formed. The organic light emitting diode display device using the bottom emission method refers to an organic light emitting diode display device in which light emitted from the organic light emitting element is emitted toward a lower side of the organic light emitting diode display device, and refers to an organic light emitting diode display device in which light emitted from the organic light emitting element is emitted toward a lower surface of the substrate on which the thin film transistor for driving the organic light emitting diode display device is formed. Furthermore, the transparent organic light emitting diode display device may be configured using a dual emission method. The organic light emitting diode display device using the dual emission method refers to an organic light emitting diode display device in which light emitted from the organic light emitting element is emitted to the upper side and the lower side of the organic light emitting diode display device and refers to an organic light emitting diode display device that may be driven simultaneously using the top emission method and the bottom emission method. Each of the organic light emitting diode display devices using the top emission method, the bottom emission method, and the dual emission method may be optimally disposed so that the thin film transistor does not interfere with an emission direction of the light emitting element by disposing the thin film transistor, the anode, and the cathode to optimize a configuration of each of the emission methods. In the following, for convenience of description, it is assumed that the transparent organic light emitting diode display device is configured using the top emission method.

Hereinafter, a description will be given of a specific configuration of the transparent display unit 140 according to an embodiment of the present disclosure.

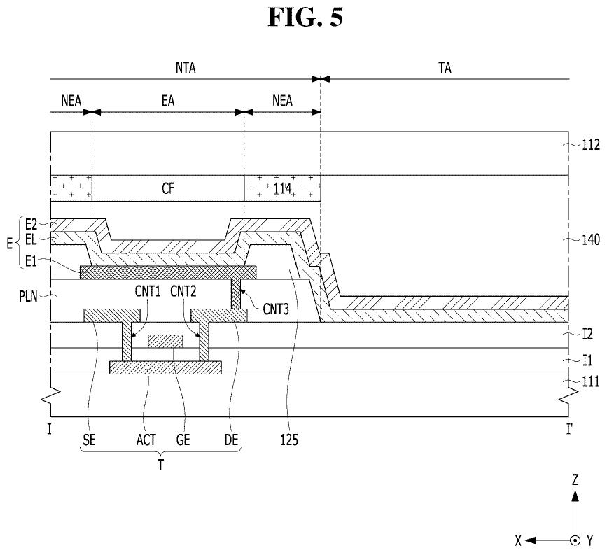

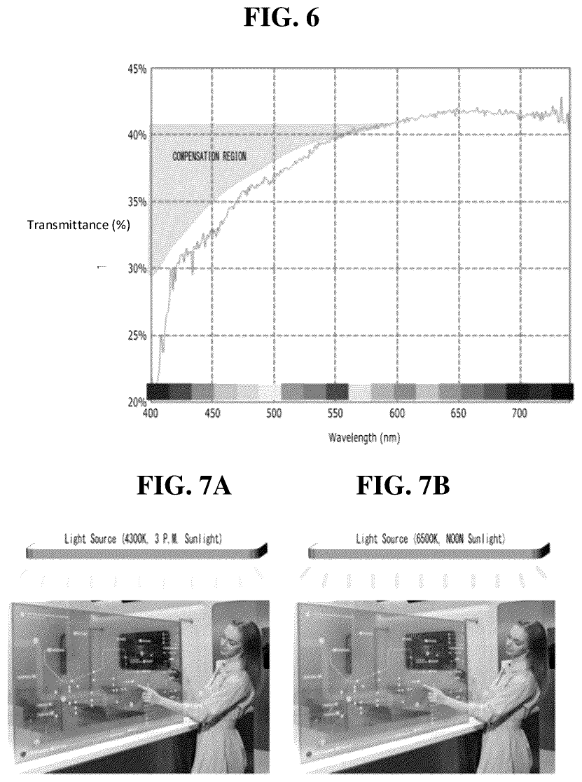

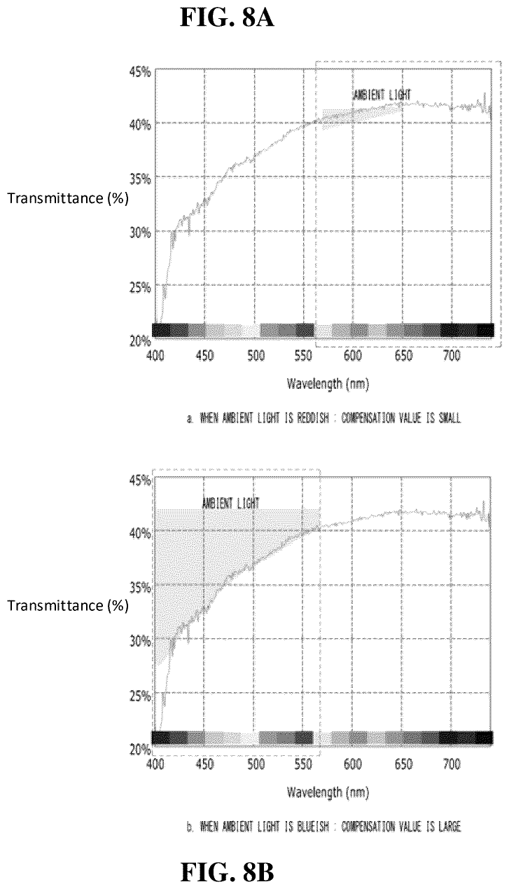

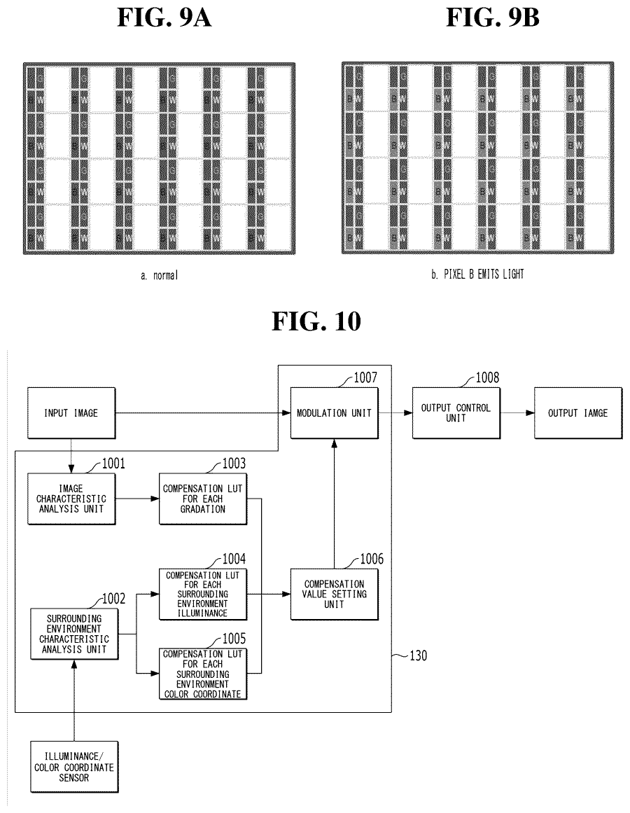

FIG. 2 is a block diagram illustrating driving of the transparent display device according to one embodiment, FIG. 3 is a diagram illustrating an example of a transparent region and a non-transparent region provided in the display area of FIG. 2 according to one embodiment, FIG. 4 is a circuit diagram of a subpixel according to one embodiment, FIG. 5 is a cross-sectional view illustrating an example of I-I′ of FIG. 3 according to one embodiment, FIG. 6 is transmittance by wavelength of the transparent display device according to one embodiment, FIGS. 7A and 7B and 8A and 8B are diagrams for describing an improvement point according to color of an external light source, and FIGS. 9A and 9B are diagrams for describing a method of improving the transparent display device.

Referring to FIGS. 2 to 9, a transparent display panel 100 according to an embodiment of the present disclosure may be divided into a display area DA in which pixels P are formed to display an image and a non-display area NDA in which no image is displayed.

As illustrated in FIG. 2, the transparent display device includes the image processor 130, a timing controller 220, a scan driver 230, a data driver 240, and a display panel 250.

The timing controller 220 may be configured in a single integrated circuit or may be configured by being patterned on a panel, and the timing controller 220 and data driver 240 may be provided in various forms such as a COG (Chip on Glass), a COF (Chip on Film), a PCB, and an FPCB (Flexible Circuit Board).

The image processor 130 provides a corrected image to the timing controller 220. The image processor 130 may receive color information of incident light from the illuminance/color coordinate sensor, and the corrected image may be an image corrected based on the color information of the incident light.

The timing controller 220 may be referred to as a driver, and the driver generates a scan control signal based on the corrected image to control the scan driver 230 and generates a data signal to control the data driver 240.

The data driver 240 receives input of a data signal from the timing controller 220. The data signal may include various signal formats such as LVDS (low-voltage differential signal), MIPI (mobile industry processor interface), RGB, etc. The data driver 240 converts the data signal through a corresponding gamma voltage and determines the amount of current flowing through the anode and the cathode of the organic light emitting element to control a light emission level of the corresponding pixel.

The scan driver 230 operates to drive a scan line so that a data signal may be input to a subpixel corresponding to each scan line. The scan driver 230 may have various structures depending on the configuration method of the subpixel. For example, when a deviation compensation circuit of the transistor is further included inside the subpixel, the scan driver 230 may include a deviation sampling scan driver for compensating for a deviation of the transistor, an emission driver for causing the corresponding pixel to emit light after sampling is performed, and a discharge driver for discharging the pixel. In addition, the scan line connected to the scan driver 230 may further include a sampling scan line, an emission scan line, and a discharge scan line.

The scan driver 230 may provide one or more scan line signals for selecting one or more scan lines described above to the transparent display unit panel 250.

A power supply unit (not shown) supplies various voltages required for the anode and the cathode of the data driver 240, the scan driver 230, and the transparent display unit panel 250. The power supply unit may supply ELVDD, ELVSS, VDD, VSS, etc. The power supply unit may be formed as a separate IC. A DC/DC converter and a PWM driver may be further included to supply the required voltages.

Hereinafter, a description will be given of driving of the transparent display unit in the transparent display device according to an embodiment of the present disclosure. The transparent display unit panel 250 includes a plurality of scan lines, a plurality of data lines, and a plurality of transparent display unit subpixels. In FIG. 3, one transparent display unit subpixel is illustrated and described for convenience of description. The scan lines extend in one direction, and the data lines extend in a direction crossing the one direction. Each of the subpixels includes a switching thin film transistor connected to each scan line and each data line, and a driving thin film transistor connected to the anode.

The timing controller 220 generates a data signal and a scan control signal based on an image signal provided from the image processor 310. The timing controller 220 provides a scan control signal for controlling the transparent display unit panel 250 to the scan driver 230 and a data signal to the data driver 240.

The scan driver 230 is connected to one end of each of the scan lines. The scan driver 230 generates a plurality of scan signals using a scan control signal provided from the transparent display unit timing controller 220 and gate on/off voltages provided from a voltage generator and applies the scan signals to gate lines arranged on the transparent display unit panel 250.

The scan driver 230 may include a plurality of gate driver ICs. The gate driver ICs may include a plurality of switching elements directly formed in a peripheral area of the transparent display unit panel 250 by the same process as that of the switching elements of the subpixel.

The data driver 240 is connected to one end of each of the data lines. The data driver 240 receives data signal gamma voltages provided from the timing controller 320. The gamma voltages may be provided from a gamma IC. The data driver 240 converts the data signal into an analog signal through a DAC corresponding to a gamma voltage generator based on the gamma voltages. The gamma voltages may be provided from the gamma voltage generator.

One end of the data line may be connected to a transparent display unit data driver 240 through a MUX. By adding the MUX, the number of wires connected to a panel and a data driver IC may be reduced.

To cause the organic light emitting layer to emit light by image information of the input data signal, a switching thin film transistor SW and a driving thin film transistor DR may be used. Depending on the plurality of thin film transistors, the number of scan lines electrically connected to one pixel may be changed, and arrangement and design of scan lines or thin film transistors may be various.

The display panel 250 displays an image in response to a scan signal and a data signal DATA supplied from a driver including the scan driver 230 and the data driver 240. A display panel 250 is implemented using the top emission method, the bottom emission method, or the dual emission method. The display panel 250 includes subpixels SPs that autonomously emit light to display an image.

As illustrated in FIG. 3, the display area DA includes a transparent region TA and a non-transparent region NTA. The transparent region TA is a region that transmits most of light incident from the outside, and the non-transparent region NTA is a region that does not transmit most of light incident from the outside. For example, the transparent region TA may be a region in which optical transmittance is greater than a %, and the non-transparent region NTA may be a region in which optical transmittance is less than B. In this instance, a is a value greater than B. In the transparent display device 100, an object or background located on a rear surface of the transparent display device 100 may be viewed due to transparent regions TAs of the transparent display panel 250.

The non-transparent region NTA includes a light emitting region EA having a plurality of pixels P that emit light. Each of the plurality of pixels P may include a first subpixel SP1, a second subpixel SP2, a third subpixel SP3, and a fourth subpixel SP4. The first subpixel SP1 may include a first light emitting region EA that emits first color light, and the second subpixel SP2 may include a second light emitting region EA that emits second color light. The third subpixel SP3 may include a third light emitting region EA that emits third color light, and the fourth subpixel SP4 may include a fourth light emitting region EA that emits fourth color light.

For example, the first to fourth light emitting regions EA may all emit light of different colors. For example, the first light emitting region EA may emit green light, and the second light emitting region EA may emit red light. The third light emitting region EA may emit blue light, and the fourth light emitting region EA may emit white light. However, the present disclosure is not necessarily limited thereto. In addition, the arrangement order of each of the subpixels SP1, SP2, SP3, and SP4 may be variously changed.

Referring to FIG. 4, each of the first to fourth subpixels SP1, SP2, SP3, and SP4 may include a switching transistor SW, a driving transistor DR, a capacitor Cst, a compensation circuit CC, and an organic light emitting diode OLED.

The switching transistor SW transmits a data signal supplied through a data line DL to a first node N1 in response to a scan signal supplied through a gate line GL. The capacitor Cst is electrically connected to the first node N1 and charged with a voltage applied to the first node N1. The driving transistor DR may control the amount of driving current flowing to the organic light emitting diode OLED in response to a voltage applied to a gate electrode.

A semiconductor layer of the switching transistor SW and/or the driving transistor DR may include silicon such as a-Si, poly-Si, or low-temperature poly-Si, or an oxide such as IGZO (Indium-Gallium-Zinc-Oxide). However, the present disclosure is not limited thereto.

The organic light emitting diode OLED outputs light corresponding to a driving current. The organic light emitting diode OLED may output light corresponding to any one of red, green, and blue colors. The organic light emitting diode OLED may include an anode, a light emitting layer formed on the anode, and a cathode supplying a common voltage. The light emitting layer may be implemented to emit light of the same color for each pixel, such as white light, or may be implemented to emit different colors for each pixel, such as red, green, or blue light.

The compensation circuit CC may be provided in a pixel to compensate for a threshold voltage of the driving transistor DR, etc. The compensation circuit CC may include one or more transistors. The compensation circuit CC may include one or more transistors and a capacitor and may be configured in various ways depending on the compensation method. A pixel including the compensation circuit CC may have various structures such as 3T1C, 4T2C, 5T2C, 6T1C, 6T2C, 7T1C, and 7T2C.

FIG. 5 is a cross-sectional view of I-I′ of FIG. 3 according to one embodiment. Referring to FIG. 5, the transparent display panel 100 according to an example of the present disclosure includes a first substrate 111 and a second substrate 112 facing each other, and a light emitting element E including a transistor T, a lower electrode E1, an organic layer EL, and an upper electrode E2 may be provided between the lower substrate 111 and the upper substrate 112.

The transistor T may include an active layer ACT provided on the lower substrate 111, a first insulating film I1 provided on the active layer ACT, a gate electrode GE provided on the first insulating film I1, a second insulating film 12 provided on the gate electrode GE, and a source electrode SE and a drain electrode DE provided on the second insulating film 12 and connected to the active layer ACT through first and second contact holes CNT1 and CNT2. In FIG. 5, the transistor T is formed in a top gate manner. However, the present invention is not limited thereto, and the transistor T may be formed in a bottom gate manner in which the gate electrode GE is placed under the active layer ACT.

A planarization film PLN may be provided on the transistor T to planarize a step caused by the transistor T and a plurality of signal lines. The planarization film PLN is provided in the non-transparent region NTA and may not be provided in at least a part of the transparent region TA. The planarization film PLN may cause light refraction in response to transmission of light, thereby reducing transparency. Accordingly, the transparent display panel 100 according to an embodiment of the present disclosure may increase transparency by removing a part of the planarization film PLN in the transparent region TA.

Meanwhile, in FIG. 5, the first and second insulating films I1 and I2 provided under the planarization film PLN are illustrated as being provided not only in the non-transparent region NTA but also in the transparent region TA. However, the present disclosure is not necessarily limited thereto. In another embodiment, some of the insulating films provided under the planarization film PLN may not be provided in at least a part of the transparent region TA to increase transparency. For example, the second insulating film I2 may be provided in the non-transparent region NTA and may not be provided in at least a part of the transparent region TA.

A bank 125 and the light emitting element E including the lower electrode E1, the organic layer EL, and the upper electrode E2 may be provided on an upper part of the planarization film PLN.

The lower electrode E1 is provided for each of the subpixels SP1, SP2, SP3, and SP4 on the planarization film PLN and may not be provided in the transparent region TA. The lower electrode E1 may be electrically connected to the transistor T. Specifically, the lower electrode E1 may be connected to one of the source electrode SE and the drain electrode DE of the transistor T through a first contact hole CNT3 penetrating the planarization film PLN. The bank 125 is provided between adjacent lower electrodes E1, and thus the adjacent lower electrodes E1 may be electrically insulated from each other.

The lower electrode E1 may be formed of a highly reflective metal material, such as a laminated structure of aluminum and titanium (Ti/Al/Ti), a laminated structure of aluminum and ITO (ITO/AI/ITO), an Ag alloy, a laminated structure of an Ag alloy and ITO (ITO/Ag alloy/ITO), a MoTi alloy, and a laminated structure of a MoTi alloy and ITO (ITO/MoTi alloy/ITO). The Ag alloy may be an alloy of silver (Ag), palladium (Pd), and copper (Cu). The MoTi alloy may be an alloy of molybdenum (Mo) and titanium (Ti). This lower electrode (E1) may be referred to as an anode.

The bank 125 may be provided on the planarization film PLN. In addition, the bank 125 may be formed to cover an edge of the lower electrode E1 and expose a part of the lower electrode E1. Accordingly, the bank 125 may prevent a problem of current being concentrated at an end of the lower electrode E1 and lowering luminous efficacy.

The organic layer EL may be provided on a first electrode layer 120. The organic layer EL may include a hole transport layer, a light emitting layer, and an electron transport layer. In this case, when voltage is applied to the lower electrode E1 and the upper electrode E2, holes and electrons move to the light emitting layer through the hole transport layer and the electron transport layer, respectively, and combine with each other in the light emitting layer to emit light. In an embodiment, the organic layer EL may be a common layer formed in common in the subpixels SP1, SP2, SP3, and SP4. In this instance, the light emitting layer may be a white light emitting layer that emits white light. In another embodiment, the light emitting layer of the organic layer EL may not be formed in the transparent region TA.

The upper electrode E2 may be provided on the organic layer EL and the bank 125. The upper electrode E2 may be formed of a transparent metal material (TCO) such as ITO or IZO that may transmit light, or a semi-transmissive metal material (semi-transmissive conductive material) such as magnesium (Mg), silver (Ag), or an alloy of magnesium (Mg) and silver (Ag). When the upper electrode E2 is formed of the semi-transmissive metal material, light emission efficiency may be increased by the microcavity effect. This upper electrode E2 may be referred to as a cathode.

A sealing film 140 may be provided on light emitting elements E. The sealing film 140 may be formed on the upper electrode E2 to cover the upper electrode E2. The sealing film 140 serves to prevent or at least reduce oxygen or moisture from penetrating into the organic layer EL and the upper electrode E2. To this end, the sealing film 140 may include at least one inorganic film and at least one organic film.

A color filter CF may be provided on one surface of the upper substrate 112 facing the lower substrate 111. The color filter CF may be pattern-formed for each of the subpixels SP1, SP2, SP3, and SP4.

Specifically, the color filter CF may include a first color filter, a second color filter, a third color filter, and a fourth color filter. The first color filter may be arranged to correspond to the light emitting region EA of the first subpixel SP1, and may be, for example, a green color filter that transmits green light. The second color filter may be arranged to correspond to the light emitting region EA of the second subpixel SP2 and may be a red color filter that transmits red light. The third color filter CF3 may be arranged to correspond to the light emitting region EA of the third subpixel SP3 and may be a blue color filter that transmits blue light. The fourth color filter may be arranged to correspond to the light emitting region EA4 of the fourth subpixel SP4 and may be a white color filter that transmits white light. The white color filter may be made of a transparent organic material that transmits white light. However, the present disclosure is not necessarily limited thereto.

A light shielding layer 114 may be provided between the color filters CFs. The light shielding layer 114 may be provided between the subpixels SP1, SP2, SP3, and SP4, and may prevent color mixing between adjacent subpixels SP1, SP2, SP3, and SP4. In addition, the light shielding layer 114 may prevent light incident from the outside from being reflected on the plurality of signal lines provided between the subpixels SP1, SP2, SP3, and SP4.

In addition, the light shielding layer 114 may be provided between the transparent region TA and the plurality of subpixels SP1, SP2, SP3, and SP4 to prevent light emitted from each of the plurality of subpixels SP1, SP2, SP3, and SP4 from proceeding to the transparent region TA. In an embodiment, the light shielding layer 114 may not be provided between the white subpixel and the transparent region TA. The display panel 100 according to an embodiment of the present disclosure may reduce the formation area of the light shielding layer 114 by not providing the light shielding layer 114 between the white subpixel and the transparent region TA. In this way, the display panel 100 according to the embodiment of the present disclosure may improve transmittance. The light shielding layer 114 may include a light-absorbing material, for example, a black dye that absorbs all light in the visible spectrum. The light shielding layer 114 may be referred to as a black matrix or BM.

The color filter CF and the light shielding layer 114 described above are not provided in the transparent region TA to maintain high optical transmittance in the transparent region TA.

The lower substrate 111 may be a plastic film, a glass substrate, or a silicon wafer substrate formed using a semiconductor process. The upper substrate 112 may be a plastic film, a glass substrate, or an encapsulation film. The upper substrate 111 and the lower substrate 112 may be made of a transparent material. The lower substrate 111 may be formed larger than the upper substrate 112, and thus a part of the lower substrate 111 may be exposed without being covered by the upper substrate 112.

As described above, the transparent display device 10 according to the embodiment of the present disclosure includes the transparent region TA that transmits incident light almost without change and the light emitting region EA that emits light. As a result, in the embodiment of the present disclosure, an object or a background located on the rear surface or the front surface of the transparent display device 10 may be viewed through the transparent regions TAs of the transparent display device 10.

Referring to FIG. 3 and FIG. 5, the organic layer EL and the upper electrode E2 of the transparent display panel 100 are formed to cover the entire panel across a light emitting portion and a transmissive portion. Due to the organic layer EL and the upper electrode E2, a visual impression of the transparent display panel of the transmissive portion tends to be yellowish. When examining transmittance by wavelength of the transparent display panel of FIG. 6, it can be confirmed that the transmittance decreases toward shorter wavelengths (blue). Roughly speaking, transmittance of short-wavelength blue light is about 10% lower than that of long-wavelength red light, and short-wavelength green light is about 5% lower than that of long-wavelength red light.

As shown in FIG. 7A, when a color temperature of an external light source is 2200 K to 4300 K, the external light source has a yellowish tint, so that the yellowish visual impression of the transparent display panel is not a problem. On the other hand, as shown in FIG. 7B, when the color temperature of the external light source is 5000 K to 6500 K, the external light source has a whiteish tint, so that the yellowish tint of the transparent display panel is visible.

As shown in FIG. 8A, even when illuminance (brightness) of the external light source and the transparent display panel are similar, if the color of the external light source is reddish, a wavelength of the external light source is similar to a wavelength of the transparent display panel, and thus a difference in visual impression is small. However, as shown in FIG. 8B, when the color of the external light source is blueish, the wavelength of the external light source is different from the wavelength of the transparent display panel, and thus the difference in visual impression may be large.

The transparent display panel tends to have a yellowish tint due to the organic layer EL and upper electrode E2 of the transmissive portion, and depending on the surrounding environment, the tint of the transparent display panel may be significantly irritating. Accordingly, the present disclosure may improve the yellowish visual impression of the transparent display panel by using the light emitting portion light source of the transparent display panel. Referring to FIGS. 9A and 9B, by emitting light from a pixel B among the pixels of the light emitting portion of the transparent display panel, the transparent display panel may be made to have an appropriate visual impression. This means that blue light is added to the existing transmitted light, the transmittance appears to increase compared to the past, and the yellowish visual impression may be improved. That is, when low-gray light is emitted from the pixel B, the visual impression of the transparent display panel may be adjusted by adding an appropriate compensation value to the existing transmitted light. Even though only the pixel B is mentioned in FIG. 9, the present disclosure is not limited thereto.

When sensing the surrounding environment, if the external light source has different illuminance (brightness) from that of the transparent display panel, referring to FIG. 6, since the transmittance decreases toward shorter wavelengths (blue), it is possible to compensate for different illuminance (brightness) between the external light source and the transparent display panel so that a visual impression of transmittance is not distorted by causing the pixel B and a pixel P to appropriately emit light. In addition, when the external light source has a different color from that of the transparent display panel, referring to FIGS. 8A and 8B, it can be confirmed that, even if illuminances of the external light source and the transparent display panel are similar, a compensation value may be different depending on the color of the external light source. When the color of the external light source is reddish, the compensation value is small. However, when the color of the external light source is blueish, the compensation value is large.

Accordingly, the present disclosure may sense the illuminance and color coordinates of the external light source in the surrounding environment in addition to transmission characteristics of the transparent display panel 10 itself, thereby calculating compensation values for each of R, G, and B of an area (transparent area) where the display image is not displayed in real time according to background characteristics that change in real time and a screen image. In addition, image data (RGB) may be corrected by adding a compensation value to an RGB data value of the area (transparent area) where the display image is not displayed.

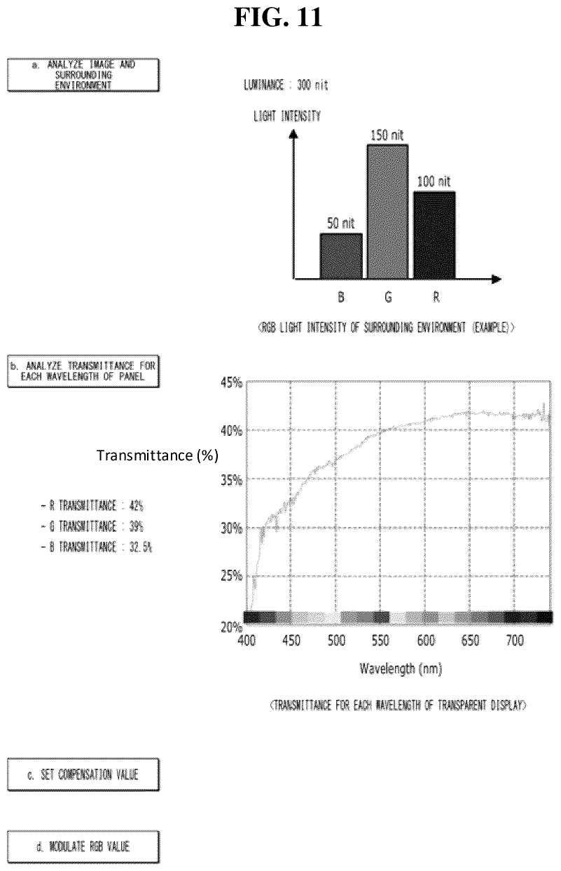

FIG. 10 is a block diagram illustrating an internal configuration of the image processor 130 according to an embodiment of the present disclosure, and FIG. 11 is a flowchart illustrating a stepwise image processing method according to an embodiment of the present disclosure. A description will be given by combining FIG. 10 and FIG. 11.

Referring to FIG. 10, the image processor 130 includes an image characteristic analysis unit 1001 (e.g., a circuit), a surrounding environment characteristic analysis unit 1002 (e.g., a circuit), a compensation lookup table (LUT) for each gradation 1003, a compensation LUT for each surrounding environment illuminance 1004, a compensation LUT for each surrounding environment color coordinate 1005, a compensation value setting unit 1006 (e.g., a circuit), a modulation unit 1007 (e.g., a circuit), and an output control unit 1008 (e.g., a circuit). In addition, the image processor 130 may further include other known image processing blocks.

The image characteristic analysis unit 1001 analyzes image data input from the outside to check the gradation. The image characteristic analysis unit 1001 may check the gradation for each of R, G, B colors of image data. In this instance, (R, G, B=r, g, b) may be checked. The image characteristic analysis unit 1001 divides the image data into an image area and a non-image area. The image characteristic analysis unit 1001 classifies an area in which R, G, and B data are all 0 in an image of one frame as the non-image area and classifies the other area as the image area. When displaying image data on a transparent panel device, the non-image area corresponds to a transparent area since there is no displayed image, and the rear surface of the transparent panel device is visible in the transparent area.

Image data of the non-image area where R, G, and B data are all 0 may be compensated by the modulation unit 1007 according to a compensation value calculated by the compensation value setting unit 1006. Here, the compensation value is calculated to improve the yellowish visual impression that occurs in an area that needs to be transparently recognized as the non-image area. That is, the image data of the non-image area where R, G, and B data are all 0 has a predetermined image data value through compensation, so that the yellowish visual impression that occurs in the area that needs to be transparently displayed may be improved.

Image data of the image area is processed in the same way as the image data of the non-image area. However, a compensation value may be set to 0.

The illuminance/color coordinate sensor SEN is provided to detect information such as intensity and color of external light existing around the transparent display panel. The external light information detected by the illuminance/color coordinate sensor SEN is provided to the surrounding environment characteristic analysis unit 1002. The illuminance/color coordinate sensor SEN may be selected from a CCD (Charge Coupled Device), a photodiode, a color sensor, etc. For example, the intensity of light may be checked.

When an abnormal tint of the transparent area of the transparent display panel is expected due to the color temperature of the external light source, the image processor 130 may compensate for an input image of the transparent area so that the transmittance by wavelength may be increased compared to before. When the amount of light loss due to a transmittance difference of the transparent area is compensated, the transmittance becomes similar by wavelength, so that the yellowish tint of the transparent display panel disappears. To set a compensation value for the amount of light loss, the compensation value setting unit 1006 may select a coefficient α from the compensation LUT for each gradation 1003, select a coefficient β from the compensation LUT for each surrounding environment illuminance 1004 in response to external light information (data information on the illuminance of the surrounding environment and the color coordinates of the surrounding environment) being transmitted from the illuminance/color coordinate sensor SEN, and select a compensation size y from the compensation LUT for each surrounding environment color coordinate 1005.

The compensation value setting unit 1006 may select coefficients and compensation sizes from each LUT to obtain the amount of light loss due to the transmittance difference for each of R, G, and B of the non-image area. The amount of loss for each color may be calculated using the following Equation 1.

$$\begin{matrix}R loss size = R light intensity of surrounding environment * ( 1 - R transmittance ) \\ G loss size = G light intensity of surrounding environment * ( 1 - G transmittance )\end{matrix} \qquad < Equation 1 >$$

B loss size=B light intensity of surrounding environment*(1−B transmittance)

In Equation 1, R, G, and B light intensities are light intensities of the surrounding environment for each of R, G, and B, and R, G, and B transmittances are transmittances of the transparent display for each wavelength. For example, when the light intensities (nit) of the surrounding environment are (100 nit, 150 nit, 50 nit) for each of (R, G, B), and transmittances are (42%, 39%, 32.5%) for each of (R, G, B), lose sizes for each of (R, G, B) may be obtained as (100 nit*(1−0.42), 150 nit*(1−0.39), 50 nit*(1−0.325)).

When the amount of light loss due to a difference in transmittance in the non-image area is compensated, the transmittance becomes similar for each wavelength, and thus the yellowish tint of the transparent display panel disappears. In addition, loss ratios of R, G, and B need to be the same to eliminate distortion of visual impression of transmission. Specifically, in the case of the transparent display panel, since the transmittance of R is the highest, excess loss of luminance of G and B occurs, and a compensation value for each color may be calculated using the following Equation 2.

$$\begin{matrix}G compensation size = G light intensity of surrounding environment * ( R transmittance - G transmittance ) \\ B compensation size = B light intensity of surrounding environment * ( R transmittance - B transmittance )\end{matrix} \qquad < Equation 2 >$$

In Equation 2, G and B light intensities are light intensities of the surrounding environment for each of R and B, and G and B transmittances are transmittances of the transparent display for each wavelength. For example, the compensation sizes for each of (G, B) may be obtained as (150 nit*(0.42−0.39), 50 nit*(0.42−0.325)). Compensation values for transmittance differences for R, G, and B may be derived by reflecting various compensation coefficients in addition to <Equation 1> and <Equation 2> given above as examples.

The modulation unit 1007 converts compensation values for each color in the G and B data of the non-image area into gradation values, then adds the values to R, G, and B data which is an existing input image, and outputs R, G, and B modulation data to the output control unit.

The output control unit 1008 sorts the modulated image data in the input order and outputs a compensated image. The compensated image output from the output control unit 1008 is supplied to the display panel through the data driver.

The transparent display device according to an embodiment of the present disclosure is not limited thereto and may correct a color of an input image using various methods.

FIG. 11 is a flowchart illustrating a stepwise image processing method according to an embodiment of the present disclosure. As shown in FIG. 11, the image processor 130 may correct the color of the input image based on histogram data for each color of the input image.

The image processor 130 may acquire histogram data for each color of the input image. A histogram for each color means data created by dividing a range in which an image exists into 2n sections, for example, for each color of R, G, and B, and detecting a frequency of appearance of data in each section.

The image processor 130 may correct an input image based on RGB values of measured incident light by correcting histogram data for each color of the input image.

The image processor 130 may perform various image processing based on the histogram data for each color. The image processor 130 may analyze the histogram data for each color and perform image processing.

As one example, the image processor 130 may be configured to analyze RGB light intensity of surrounding environment and analyze transmittance for each wavelength of the panel. The image processor 130 may be configured to calculate a compensation value for each color based on light intensity of surrounding environment and a transmittance difference for each of R, G, and B of the non-image area. The image processor 130 may be configured to reflect the compensation value for each color in the image data to output the modulation data.

In this specification, when the transparent display device according to an embodiment of the present disclosure performs image processing to correspond to color information of incident light, histogram shifting, histogram stretching, etc. are described as examples. However, the present disclosure is not limited thereto, and the transparent display device 400 may perform input image color correction based on a color of the incident light through various forms of image processing.

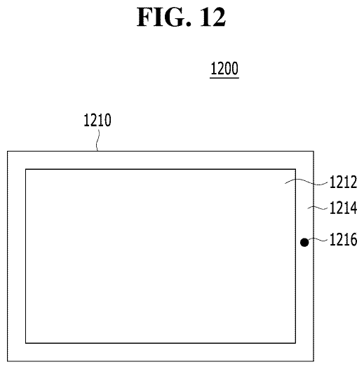

FIG. 12 illustrates a location of the illuminance/color coordinate sensor 1216 in the transparent display device according to an embodiment of the present disclosure. The transparent display device according to the embodiment of the present disclosure includes a light transmitting display area 1212 and a non-display area 1214.

The location of the illuminance/color coordinate sensor 1216 in the transparent display device according to the embodiment of the present disclosure is not limited. The illuminance/color coordinate sensor 1216 may be arranged without limitation as long as the illuminance/color coordinate sensor 1216 is arranged on one surface of the transparent display device and may measure light incident on the illuminance/color coordinate sensor 1216. In the transparent display device according to an embodiment of the present disclosure, the illuminance/color coordinate sensor 1216 may be arranged on the front surface, the rear surface, or the side surface of the transparent display device. For example, when the transparent display device includes a plurality of sensors, the plurality of illuminance/color coordinate sensors 1216 may be independently driven, and the transparent display device may recognize location information of each of the illuminance/color coordinate sensors 1216. In addition, as the number of illuminance/color coordinate sensors 1216 increases, color measurement may become more accurate.

In FIG. 12, the illuminance/color coordinate sensor 1216 of the transparent display device is arranged in a non-display area 1214 on one surface of the transparent display device. To more accurately measure light incident on the transparent display device, the illuminance/color coordinate sensor 1216 may be arranged in a center of the transparent display device.

Even though the present disclosure has been described in more detail with reference to the embodiments, the present disclosure is not necessarily limited to these embodiments, and various modifications may be made without departing from the technical idea of the present disclosure. Accordingly, the embodiments disclosed in the present disclosure are not intended to limit the technical idea of the present disclosure, but to describe the technical idea, and the scope of the technical idea of the present disclosure is not limited by these embodiments. The protection scope of the present disclosure should be interpreted by the following claims, and all technical ideas within a scope equivalent thereto should be interpreted as being included in the scope of the rights of the present disclosure.

What is claimed is:

1. A transparent display device comprising:
a transparent display unit comprising a plurality of pixels configured to display an image and a plurality of transmissive portions arranged adjacent to the plurality of pixels;
at least one optical sensor configured to measure optical characteristics of light that is incident on the transparent display unit; and
an image processor configured to correct image data of a non-image area in the image data based on the optical characteristics.

2. The transparent display device according to claim 1, wherein the at least one optical sensor is configured to measure illuminance of light incident on a rear surface of the transparent display unit.

3. The transparent display device according to claim 1, wherein the at least one optical sensor is configured to measure color coordinates of light incident on a rear surface of the transparent display unit.

4. The transparent display device according to claim 2, wherein the image processor compensates at least one of green data or blue data of the image data based on the optical characteristics and transmittance of red of the transparent display unit.

5. The transparent display device according to claim 2, wherein the image processor comprises:
an image characteristic analysis circuit configured to analyze gradation of the image data to determine an image area and the non-image area;
a compensation value setting circuit configured to calculate a compensation value for each color based on a transmittance difference for each of R, G, and B of the non-image area; and
a modulation circuit configured to reflect the compensation value for each color calculated by the compensation value setting circuit in the image data to output modulation data.

6. The transparent display device according to claim 1, wherein the image processor sets a compensation value of data of an image data in the image data to 0.

7. The transparent display device according to claim 1, wherein a pixel B and a pixel G of the non-image area in which an image is not displayed among pixels of a light emitting portion of the transparent display unit are caused to emit light.

8. The transparent display device according to claim 1, wherein the image processor is configured to correct the image by analyzing a color histogram of the image.

9. A transparent display device comprising:
a transparent display unit comprising a plurality of pixels configured to display an image and a plurality of transmissive portions arranged adjacent to the plurality of pixels;
at least one optical sensor configured to measure color information of external light that is incident on a rear surface of the transparent display unit; and
an image processor configured to correct data having a zero data value in input image data of the transparent display unit based on the color information of the external light.

10. The transparent display device according to claim 9, wherein the image processor compares the color information of the external light with previously stored transmittances of the transparent display unit and corrects the input image data based on color having high transmittance.

11. A controlling method of transparent display device, the transparent display device including a transparent display unit configured to display an image, the controlling method comprising:
measuring optical characteristics of light incident on the transparent display unit; and
correcting image data of a non-image area in the image data based on the optical characteristics.

12. The controlling method according to claim 11, further comprising measuring illuminance of light incident on a rear surface of the transparent display unit.

13. The controlling method according to claim 11, further comprising measuring color coordinates of light incident on a rear surface of the transparent display unit.
